(19) United States
(12) Patent Application Publication
(10) Pub. No.: US 2005/0215063 A1
(43) Pub. Date: Sep. 29, 2005

(54) System and methods for etching a silicon wafer using HF and ozone

(76) Inventor: Eric J. Bergman, Kalispell, MT (US)

Correspondence Address: PERKINS COIE LLP/SEMITOOL, PO BOX 1208, SEATTLE, WA, 98111-1208, US

(21) Appl. No.: 10/975,194

(22) Filed: Oct. 27, 2004

Related U.S. Application Data
(63) Continuation-in-part of application No. 10/631,376, filed on Jul. 30, 2003.
Application No. 10/631,376 is a continuation-in-part of application No. 09/621,028, filed on Jul. 21, 2000, now Pat. No. 6,869,487.
Application No. 10/631,376 is a continuation-in-part of application No. 08/853,649, filed on May 9, 1997, now Pat. No. 6,240,933.
Application No. 10/631,376 is a continuation-in-part of application No. PCT/US99/08516, filed on Apr. 16, 1999.
Application No. 10/631,376 is a continuation-in-part of application No. 09/061,318, filed on Apr. 16, 1998, now abandoned.
(60) Provisional application No. 60/145,350, filed on Jul. 23, 1999.
(60) Provisional application No. 60/125,304, filed on Mar. 19, 1999.
(60) Provisional application No. 60/099,067, filed on Sep. 3, 1998.

(51) Int. Cl. H01L 21/302

(52) U.S. Cl. 438/710; 134/200

(57) ABSTRACT

In a method of etching a silicon wafer in a controllable cost-effective manner with minimal chemical consumption, ozone gas and HF vapor are delivered into a process chamber to react with a silicon surface of the wafer. The ozone and HF vapor may be delivered sequentially, or may be mixed together before entering the process chamber. The ozone oxidizes the silicon surface of the wafer, while the HF vapor etches away the oxidized silicon. In alternative embodiments, HF may be delivered into the process chamber as an anhydrous gas or in aqueous form.

This application is a Continuation-in-Part of U.S. patent application Ser. No. 10/631,376, filed Jul. 30, 2003, and now pending, which is a Continuation-in-Part of U.S. patent application Ser. No. 09/621,028, filed Jul. 21, 2000 and now pending, which is:
[1] a Continuation-in-Part of Ser. No. 60/145,350 filed Jul. 23,1999;
[2] a Continuation-in-Part of Ser. No. 08/853,649, filed May 9, 1997 and now U.S. Pat. No. 6,240,933; and
[3] a Continuation-in-Part and U.S. National Phase Application of International Application PCT/US99/08516, filed Apr. 16, 1999, which in turn is a Continuation-in-Part of each of U.S. Patent Application Ser. Nos. 60/125,304 filed Mar. 19, 1999; 60/099,067 filed Sep. 3, 1998; and Ser. No. 09/061,318, filed Apr. 16, 1998. The applications listed above are incorporated herein by reference.

### BACKGROUND OF THE INVENTION

Silicon wafer etching is an important step in manufacturing semiconductor devices and micro-electro mechanical systems (MEMS). In the past, solutions containing strong oxidizers such as nitric acid (HNO₃) and hydrofluoric acid (HF) have been used for silicon wafer etching. The chemical reactions for this process generally proceed as follows:
Si+2HNO₃→SiO₂+2NO₂ (silicon oxidation)
4HF+SiO₂→SiF₄+2H₂O (dissolution of silicon dioxide)

Silicon etching results from the formation of silicon dioxide via the chemical reaction between silicon and an oxidizing agent (HNO₃), followed by the reaction of the silicon dioxide with fluorine to form silicon tetrafluoride (SiF₄), which can be dissolved in an aqueous carrier or evolved as a gas. While numerous oxidizing agents have been experimented with, if any, few effective alternatives to fluorine have been found.

One problem with this process is that it is difficult to control, due to the consumption of reactants and the evolution of nitrous oxides which dissolve into the etchant solution, thereby “poisoning” the bath by saturation, which will affect subsequent etches. The process also requires large volumes of expensive process chemicals, involves a great deal of hazardous waste, and is difficult to control to the extent required in order to deliver optimal etch uniformity.

Alternative silicon etchants include caustic solutions such as potassium hydroxide or sodium hydroxide, or fluorine plasma chemistries such as SiF₆. The two primary classes of silicon etchants can thus be classed as either aqueous chemistries applied in the liquid state (e.g., HNO₃, HF, or caustics), or fluorine plasmas. Each of these process categories has certain applications and limitations.

In the case of aqueous chemistries, limitations include the cost of the chemicals, the need for significant amounts of water for rinsing, the creation of large volumes of waste (chemical and rinse water), and the inability to deliver the etchant into small geometries, which are common in semiconductor devices and MEMS devices. In general, caustics are not favored in the semiconductor industry, due to commonly known problems associated with mobile ion contamination. This is especially true of elements such as Na and K.

In the case of plasma chemistries, the cost of the processing equipment and supporting hardware (e.g., vacuum pumps) can be quite high. Many plasma processes are designed to deliver an anisotropic etch profile. While this has many desirable features, it has a tendency to create very sharp corners on device geometries, which can lead to failure of the microelectronic or MEMS device. Many of these systems are also designed for single-wafer processing, which can increase required manufacturing time. Additionally, plasmas are relatively expensive and may tend to generate contaminant particles.

Thus, there is a need for an improved systems and methods for etching silicon wafers used in semiconductor devices and/or MEMS devices.

### SUMMARY OF THE INVENTION

The present invention is directed to a method of etching a silicon wafer using ozone and HF. The ozone oxidizes one or more layers of silicon on the wafer surface, and the HF etches away the oxidized silicon layer.

In a first aspect, ozone gas is delivered into a process chamber containing one or more silicon wafers. HF vapor is delivered into the process chamber, either simultaneously with the ozone gas, or after the ozone gas delivery has begun. The HF vapor is preferably delivered via a carrier gas, which may also be ozone gas, or may be an inert gas. The HF vapor etches the oxidized silicon layer.

In another aspect, ozone gas is delivered into a process chamber containing one or more silicon wafers. Anhydrous HF gas is delivered into the process chamber while deionized (DI) water is sprayed onto a surface of the wafers. The anhydrous HF gas dissolves into the DI water, which may form a microscopic aqueous boundary layer on the wafer surfaces, and etches the oxidized silicon layer on the wafer surfaces. The wafers may be rinsed after the etching process is completed.

In another aspect, in an entirely gas/vapor phase process, ozone gas is delivered into a process chamber containing one or more silicon wafers to oxidize a layer of silicon on the wafers into SiO₂. HF is delivered into the process chamber to react with the SiO₂ layer and convert the SiO₂ layer into gas phase SiF₄. The SiF₄ gas is then removed from the process chamber. The reaction continues unimpeded by reaction by-products, until the desired etching is completed.

In yet another aspect, the methods described above are performed, but with HF condensing on the wafer, or with the HF provided in liquid form.

In another aspect, a system is provided for carrying the methods described.

Any of the described processes may be combined and/or repeated one or more times to achieve optimal results. Other features and advantages of the invention will appear hereinafter. The invention resides as well in sub-combinations of the features described, as well as in the system or apparatus shown in the drawings and described below.

### BRIEF DESCRIPTION OF THE DRAWINGS

FIG. 1 is a perspective view of a wafer processing system.

FIG. 2 is a front view of the wafer processing system illustrated in FIG. 1.

FIG. 3 is a schematic diagram of a wafer processing system that may be used to perform wafer etching.

### DETAILED OF DESCRIPTION OF THE DRAWINGS

In a method of etching a silicon wafer, ozone gas or vapor is delivered into a process chamber containing one or more silicon wafers. The ozone oxidizes one or more layers of silicon on the wafer surfaces. The HF then dissolves or etches away the oxidized silicon layers. With the ozone and HF both provided as a gas or vapor, simultaneously, or near simultaneously, under conditions where there is no condensation, wafer etching is achieved without applying any liquid to wafer surface (and without the need for plasma chemistries).

The HF may be provided in vapor form, anhydrous gas form, or alternatively, aqueous form. The HF may also be delivered shortly following, the delivery of the ozone into the process chamber. Other steps and features described below may be advantageous but are not necessarily essential to the invention.

The methods described herein for processing silicon wafers, which provide support or are substrates for semiconductor devices and/or MEMS devices, may be performed in a variety of processing systems. Conventional semiconductor wafer processing systems, for example, may be used to process the silicon wafers. Moreover, one or more processing systems may be used to perform the various processing steps described herein. Thus, the processing system 10 described below is only one example of a processing system that could be used to process silicon wafers according to the claimed methods.

To maintain the wafer surfaces hydrophobic (and thereby control adhesion of contaminants to the wafer surfaces), in the past, generally only very dilute HF solutions have been used. These dilute HF solutions have limited the etch rate (on thermal oxide) to about 20 angstroms/minute, and with the etch rate of polysilicon limited to about 20-60 angstroms per minute. In one aspect of the present methods, by applying the oxidizer as a gas and the HF as a vapor, these limitations are largely overcome. Using the present methods, etch rates on polysilicon of over 400 angstroms per minute have been reached. In addition, no rinsing is required, because the ozone and HF are applied as a gas or vapor, and not a liquid, and the reaction by-product SiF₄ is also a gas. Thus the surface state of the silicon (whether hydrophobic or hydrophilic) has no effect on whether contaminants such as particles are attracted or adhered to the silicon surfaces, because this process involves no liquids.

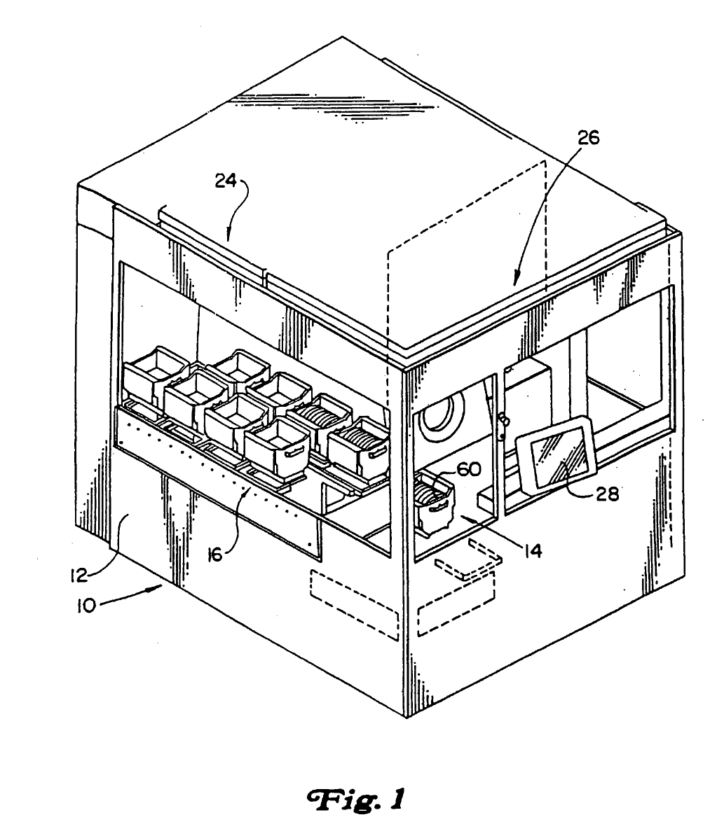

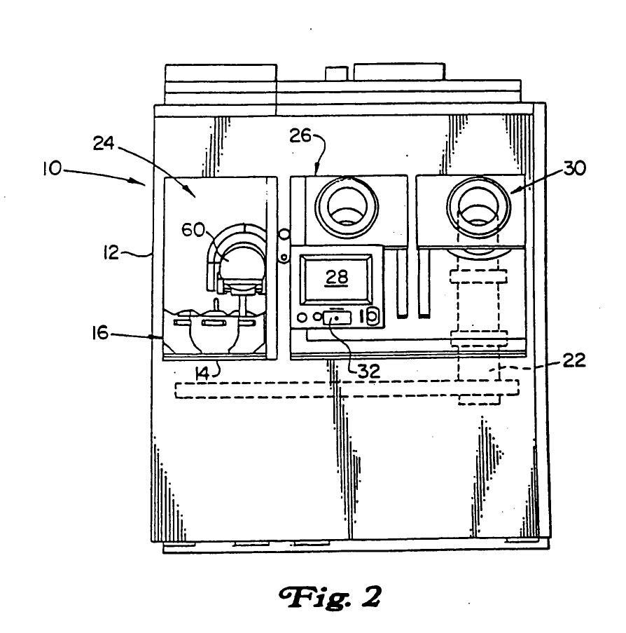

Turning now in detail to the drawings, as shown in FIGS. 1 and 2, a wafer processing system 10 advantageously includes an enclosure 12 to maintain and control clean airflow and reduce contamination of wafers being processed in the processing system 10. An input/output station 14 at the front of the system 10 allows wafers 60 to be loaded and unloaded to and from the system 10. An indexer 16, or other temporary wafer storage station, is preferably provided adjacent to the input/output station 14.

The system 10 may be divided into an interface section 24 and a process section 26. These sections may be separated by a partition having a door opening. The interface section 24 includes the input/output station 14 and the indexer 16. The process section 26 includes one or more process stations 30, with each process station 30 including a wafer processor. The interface section 24 also preferably includes a process robot 22 for moving wafers 60 between the indexer 16 and the processor unit. A control panel 28 may be provided on the enclosure 12, to allow instructions or programming to be input into a computer controller 32 which controls the system 10.

The wafers 60 may be provided in open carriers, cassettes, or trays, and handled as described in U.S. Pat. Nos. 6,279,724 or 5,664,337, both incorporated herein by reference. Alternatively, the wafers 60 may be provided within sealed pods or containers which are unsealed at a docking station, as described in U.S. Pat. No. 6,447,232 or U.S. patent application Ser. Nos. 09/612,009 or 10/200,074, each incorporated herein by reference.

The processors 30 in the processing system 10 may be batch processors or single wafer processors (e.g., as described in U.S. Pat. No. 6,423,642, incorporated herein by reference), similar to those used in existing semiconductor wafer processing systems. Several variations of batch processors and/or single wafers processors may be used. For example, a batch processor with a 25-wafer capacity, or alternatively, a 50-wafer capacity, may be used. A system with a single processor may also be used. In a more basic form, the processor can be a stand alone manually loaded and operated unit.

In the specific design shown in the drawings, the processors 30 each include a rotatable wafer holder or rotor, so that the wafers 60 may be rotated during processing. Rotation of the wafers 60 may be used for distributing process fluids evenly across the wafer surfaces, for spin-drying the wafers 60, or for other reasons.

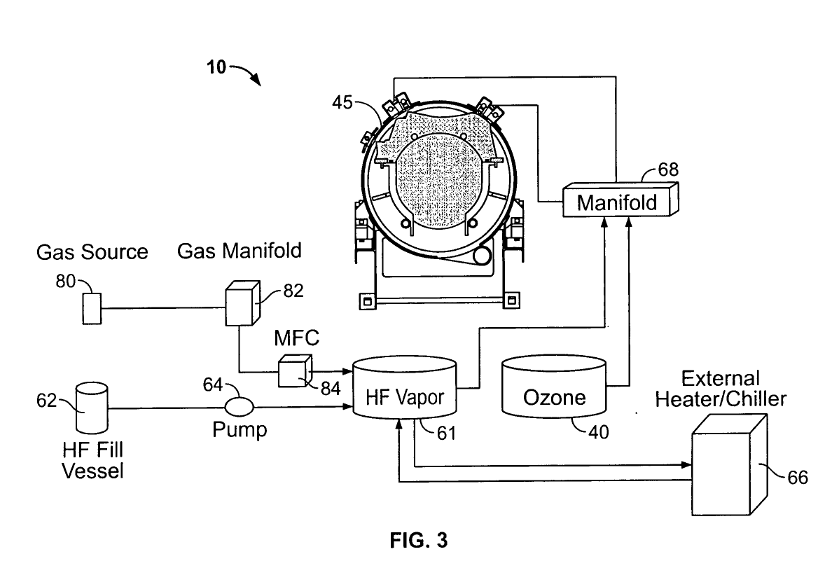

FIG. 3 is a schematic flow diagram of a wafer processing system. In operation, one or more wafers 60 are loaded into a wafer holder or rotor in a process chamber 45, which may be a batch processor or a single wafer processor. The wafers 60 may be loaded manually, by a robot, or by another suitable loading device. The wafers 60 may be handled or contacted directly by the robot or rotor. Alternatively, the wafers 60 may be handled within a carrier tray or cassette, which is placed into the rotor or other holder.

Once the wafers 60 are loaded into the processor, the process chamber 45 is closed, and may optionally form a gas and/or fluid-tight seal. Ozone (O₃) gas is then provided into the process chamber from an ozone source 40. The ozone gas may be delivered into the process chamber 45 via a manifold 68, nozzles, or another suitable device. The ozone gas fills the process chamber 45 to form an ozone environment. The ozone may alternatively be mixed with HF vapor before entering the process chamber 45, and/or may be used as a carrier gas for HF vapor, as described below.

The ozone oxidizes one or more layers of silicon on the wafers 60, converting the silicon to silicon dioxide (SiO₂). Pure oxygen (O₂) may alternatively be used to convert the silicon layer into silicon dioxide. The silicon oxidizing reaction generally proceeds as follows:
Si+2O₃→SiO₂+2O₂
Or
Si+O₂→SiO₂

HF vapor is provided into the process chamber 45 to etch the oxidized silicon layer. To generate the HF vapor, HF liquid may be provided in an HF fill vessel 62, and then pumped into an HF vaporizer 61 with a pump 64. The HF vaporizer 61 is preferably connected to a heat exchanger 66, which may provide heat to the HF vaporizer 61 to convert the HF liquid into HF vapor. In general, the vapor may be generated as described in U.S. Pat. No. 6,162,734, incorporated herein by reference. The generated HF vapor is provided into the process chamber via the vapor delivery manifold 68, or another suitable device.

The HF vapor may be delivered into the process chamber 45 after the ozone begins to enter the process chamber 45, or it may be mixed with the ozone before entering the process chamber 45. The silicon surface of a wafer 60 is oxidized by the ozone, and the oxidized surface is then etched by the HF vapor. The wafers 60 may be rotated in the rotor to promote mixing and/or chemical distribution on the wafer surfaces.

The HF vapor is preferably mixed with a carrier gas, such as nitrogen (N₂) gas, for delivering the HF vapor into the process chamber 45, as is common in the semiconductor wafer manufacturing industry. N₂ gas, or a gas with similar properties, may also be delivered to the process chamber 45 after the wafers 60 are processed, in order to purge any remaining HF vapor from the process chamber 45 before the chamber door is opened. The use of HF vapor in conjunction with a carrier gas, as well as possible configurations for generating HF vapor for use in etch applications, is described in U.S. Pat. Nos. 5,954,911 and 6,162,735, incorporated herein by reference.

Other gasses, such as compressed dry air, oxygen, and CO₂, could alternatively be used as a carrier gas. Ozone gas may also be used as the carrier gas, and may be preferable in some applications, since it is integral to the oxidizing process, and would minimize the dilution effects of using an inert gas, such as nitrogen. When ozone is used as the carrier gas, the “carrier” gas is active, i.e., it chemically reacts inside the process chamber. The carrier gas is preferably delivered from a gas source 80 into gas manifold 82. The carrier gas exits the manifold 82 and is delivered through a mass flow controller (MFC) 84 into the HF vaporizer 61, and to any other desired system components. The MFC is preferably an electronic device that controls the mass of the carrier gas that flows to the other system components.

The carrier gas passes through the HF vaporizer 61, where it entrains the HF vapors and carries them to the process chamber 45 to react with the oxidized silicon layer, or other material to be etched. To generate the HF vapor, the carrier gas may be bubbled through the HF solution in the HF vaporizer 61, or may be flowed across the surface or the HF solution, thereby becoming enriched in HF and water vapor. Alternatively, the HF vapor may be generated by heating or sonically vaporizing the HF solution. The selection and delivery technique for the carrier gas, and the delivery technique of the HF are not essential and may be varied.

When the HF vapor enters the process chamber 45, it may form a visible condensate film on the surface of the wafers 60. Regardless of whether a visible condensate film is formed, a microscopic aqueous boundary layer, which is condensed from the gas/vapor phase environment in the process chamber 45, is preferably formed on the wafer surface. HF vapor and/or ozone are present in the microscopic boundary layer as dissolved or diffused species from the surrounding gas/vapor environment.

There is a significant distinction between a microscopic boundary layer and a macroscopic boundary layer, which is often used in semiconductor wafer cleaning (as opposed to etching). The microscopic boundary layer is a condensed phase layer formed from a vapor/gas environment, whereas a macroscopic boundary layer is a visible liquid formed on the wafer surface by spraying or otherwise delivering an aqueous solution onto the wafer surface. The microscopic film or layer may be difficult to detect. While there are technologies available to detect the presence of the film (such as laser interferometry) the presence of the film is more easily established by implication. For example, one indication of the presence of the film would be when an increase in the temperature in the chamber results in a decrease in the etch rate. Contrary to this observation, kinetic theory would predict an increase in etch rate with an increase in temperature (the Arhenius equation). The decrease occurs because at higher temperatures the condensed film does not form as readily, thereby decreasing the concentration of reactants at the wafer surface. Since all rate equations are a function of reaction species and temperature, the implication is that the concentration of reactants at the point of reaction has been reduced, i.e. that the film while present at the lower temperature had been reduced or eliminated at the higher temperature.

The objective in wafer etching is to form a microscopic liquid boundary layer on the wafer surface that has condensed from the gas/vapor phase. Because the layer or film is microscopic, the wafer surface never becomes “wet” in the conventional wafer-cleaning sense. Thus, rinsing and drying are typically not required or used in the present wafer etching methods, whereas rinsing and drying are typically required in semiconductor cleaning operations. Rinsing and drying may optionally be used with the present methods, however, after the etching process is completed, to remove any contaminants from the wafer surface.

The HF vapor enters the process chamber and begins to etch the silicon dioxide film on the wafers 60. Fresh ozone gas is preferably continuously supplied into the process chamber 45 during the etching process, in order to continually oxidize the exposed silicon surface of the wafer. The HF vapor reacts with the silicon dioxide to form silicon tetrafluoride (SiF₄), which may then be evolved as a gas and removed via a system exhaust, or may be dissolved in an aqueous carrier liquid. The silicon dioxide dissolution reaction generally proceeds as follows:
4HF+SiO₂→SiF₄+2H₂O

Thus, the entire oxidizing and etching process is generally as follows:
Si+2O₃→SiO₂+2O₂
Or
Si+O₂→SiO₂
4HF+SiO₂→SiF₄+2H₂O

Target etch rates range from about 500 to about 20,000 Angstroms/minute, with 2000 to about 5000 Angstroms/minute being typical. The silicon surface is continuously etched in the presence of HF vapor and ozone until the desired amount of etch is achieved. Because vaporous HF is used, no rinsing or drying step is required, although rinsing and drying may be used if desired. Only a small amount of HF is required to etch the wafers. Consequently, there is less HF chemical waste to be disposed of. The present methods are accordingly more environmentally friendly than methods used in the past.

In an alternative embodiment, HF is delivered into the ozone-filled process chamber as an anhydrous gas. Anhydrous HF gas does not generally produce a significant etch rate on silicon dioxide films. In order for the etch rate to become significant for most applications, the anhydrous HF gas must be mixed with water so that it is no longer anhydrous. The presence of water vapor appears to catalyze the reaction. The absence of water renders the HF gas essentially inert in regards to silicon dioxide. Thus, the anhydrous HF gas is preferably either mixed with water prior to delivery to the wafer surface, or mixed with an aqueous layer on the wafer surface.

In one preferred method, deionized (DI) water, maintained at a controlled temperature, is sprayed onto a wafer surface simultaneously with the delivery of anhydrous HF gas into the process chamber. The anhydrous HF gas dissolves in the DI water, causing the anhydrous HF gas to become aggressive toward the silicon dioxide on the wafer surface. The anhydrous HF gas, mixed with water, etches the silicon dioxide film on the wafer surface. The etch product (SiF₄) may then be evolved as a gas and removed via a system exhaust, or may be dissolved in an aqueous carrier liquid

The anhydrous HF gas may alternatively be bubbled into water, or mixed with a water vapor or aerosol, within the processing chamber, or prior to entering the processing chamber. In the latter cases, HF vapor is generated by mixing anhydrous HF gas with water vapor. The anhydrous HF gas may also be mixed with ozone before being delivered into the process chamber. Regardless of how the anhydrous HF gas and the ozone enter the process chamber, both HF and ozone are preferably present in the microscopic aqueous boundary layer at the wafer surface, as described above.

In another embodiment, HF may be delivered into the process chamber as an aqueous solution. The HF solution may have other additives such as ammonium fluoride as a buffer, organic solvents such as ethylene glycol to help promote surface wetting and control ionization, or other commonly used additives. HF and water, however, are preferably the key components to the solution. The other processing steps are performed as described above to thin the wafers. Spinning or rotating the wafers, in this embodiment, may be used to mix or distribute the liquid solution across the wafer surface, and/or to also help to control the thickness of the liquid layer on the wafers. However, spinning is not essential in any of the described methods. When spinning is used, the orientation of the spin axis, vertical, horizontal, or in-between, typically is not important, and any convenient spin axis can be used.

While the primary focus of the present invention is the use of ozone and HF for the purpose of etching silicon wafers, other gas mixtures and additives may also be used to accomplish specific cleaning purposes. For example, alcohol or alcohol mixtures may be used to help control etch selectivity between various film types exposed to the etchant vapors. HCl may be used to enhance the removal of metal contaminants.

Additionally, several options are viable to conclude the etch processes. For example, a rinse with DI water or another suitable agent may be performed to quench the process. Additionally, the delivery of HF vapor may be continued without ozone to provide an oxide-free hydrophobic silicon surface, or conversely, the delivery of ozone may be continued without HF vapor to ensure an oxidized hydrophilic silicon dioxide surface. Other processes may also be performed to meet the needs of a specific application.

The present methods use less expensive and more controllable techniques than those currently practiced. In order to accomplish this, ozone gas is used as a silicon oxidizer, and HF vapor or gas is used to etch the oxidized silicon.

Potential benefits of the described methods are that they:
(a) minimize chemical consumption and waste generation in silicon wafer etching applications;
(b) eliminate the requirement for a post-etch rinse (in some embodiments, such as the vapor phase reaction). This may be especially useful with MEMS devices where rinsing can cause defects resulting from surface tension effects;
(c) readily lend themselves to a single-side application, where the non-processed side of the wafer would only need to be protected from vapor species (which is much more easily accomplished than is protection from liquid reactants);
(d) lend themselves equally well to batch processing;
(e) create a final wafer surface state (oxidized or bare silicon) that can be easily controlled;
(f) have the potential to etch other materials, such as gallium arsenide. This is another family of compounds which are often etched with liquid chemistries containing an oxidizing agent such as hydrogen peroxide, and something to dissolve the oxide which is formed. Chemicals such as HCl, H₂SO₄ or NH₄OH (among others) are commonly used. In this case, one of the significant benefits would be the elimination of H202 which degrades relatively quickly, thereby rendering the etchant bath unstable;
(g) deliver etchants into submicron geometries without encountering problems caused by the etchant's surface tension;
(h) eliminate particle and other contamination deposition on the hydrophobic surface during etching; and
(i) improve silicon surface roughness, particularly after plasma etching which tends to create almost a serrated or stepped pattern in the silicon sidewall. This may be especially important in order to improve breakdown performance of oxides used in gate oxide applications, trench capacitors and trench transistor structures.

### EXAMPLE I

In several tests, an Astex 8403 ozone generator was configured to deliver ozone at 282 g/m3 and 10 slpm. A nitrogen supply was connected to an HF vapor generator. The vapor generator contained liquid HF (49% wt.) at 22 C and the nitrogen was passed across the surface of the HF through a path defined by a spiral baffle to force intimate contact with the liquid surface. The nitrogen flow was set at 10 slpm. As the nitrogen flow exited the vapor generator, enriched with HF vapor, it was converged with the ozone stream. The gas/vapor mixture was then delivered to the processing chamber of a Semitool Spray Acid Tool. 200 mm monitor wafers were rotated at 200 RPM during gas/vapor delivery. While this rotation helps to ensure homogenous mixing within the process chamber, it is not necessary to perform the methods. At the conclusion of the etch step, the gas/vapor was purged from the chamber with nitrogen. Polysilicon etch monitors showed an etch rate of 459 angstroms per minute, and thermal oxide etch rates were similar. The process was done without using any water, using less than 2 ml of HF and without creating any waste other than exhaust. Previous tests have shown that vapor processes similar to this can be delivered into geometries that have aspect ratios in excess of 50:1, can penetrate submicron geometries and leave no significant residue while being essentially particle neutral. Subsequent tests using different parameters resulted in etch rates up to about 1 micron.

The essential elements of the system 10 as shown in FIG. 3 are the HF source 61, the ozone source 40, and the process chamber 45. The other substantially non-essential elements shown in FIG. 3 may also be used in combination with these essential elements.

While the term wafer as used here generally refers to silicon or semiconductor wafers, it also encompasses similar flat media articles or workpieces which may not be silicon or a semiconductor, but which may be etched as described above. The singular use of the term wafer above also includes wafers, i.e., more than one wafer.

While embodiments and applications of the present invention have been shown and described, it will be apparent to one skilled in the art that other modifications are possible without departing from the inventive concepts herein. The invention, therefore, is not to be restricted except by the following claims and their equivalents.

1. A method of etching one or more wafers, comprising:
placing the wafer into a process chamber;
delivering ozone gas into the process chamber;
oxidizing a wafer surface with the ozone;
delivering HF vapor into the process chamber; and
etching the oxidized wafer surface with the HF vapor.

2. The method of claim 1 wherein the HF vapor is delivered into the process chamber via a carrier gas.

3. The method of claim 2 wherein the carrier gas comprises ozone.

4. The method of claim 2 wherein the carrier gas comprises an inert gas.

5. The method of claim 4 wherein the inert gas is mixed with the ozone before the ozone enters the process chamber, such that the ozone and the HF vapor are simultaneously delivered to the wafer.

6. The method of claim 1 further comprising the step of forming a condensate film of HF vapor on a surface of the wafer.

7. A method of etching one or more silicon wafers, comprising:
placing the wafer into a process chamber;
delivering ozone gas into the process chamber to oxidize a layer of silicon on the wafer;
delivering anhydrous HF gas into the process chamber;
spraying DI water onto a surface of the wafer substantially simultaneously with the step of delivering anhydrous HF gas into the process chamber;
dissolving at least some of the anhydrous HF gas into the DI water on the wafer surface; and
etching the oxidized silicon layer with the dissolved anhydrous HF gas.

8. The method of claim 7 wherein the ozone gas and the anhydrous HF gas are mixed with one another before being delivered into the process chamber.

9. The method of claim 7 further comprising the step of forming a boundary layer of DI water on the surface of the wafer.

10. The method of claim 7 further comprising the step of spinning the wafer.

11. A method of etching one or more silicon wafers, comprising:
placing the wafer into a process chamber;
delivering ozone gas into the process chamber to oxidize a layer of silicon on the wafer;
delivering HF into the process chamber to etch the oxidized layer; and
forming a microscopic aqueous layer on the wafer surface.

12. The method of claim 11 wherein the HF is delivered into the process chamber in vapor form.

13. The method of claim 12 wherein the HF vapor is delivered into the process chamber via a carrier gas.

14. The method of claim 13 wherein the ozone acts as the carrier gas.

15. The method of claim 11 wherein the ozone gas and the HF are mixed together before being delivered into the process chamber.
